(19) United States
(12) Patent Application Publication
(10) Pub. No.: US 2026/0079184 A1
(43) Pub. Date: Mar. 19, 2026

(54) CURRENT MEASUREMENT SYSTEM AND CURRENT MEASUREMENT DEVICE

(71) Applicant: Infineon Technologies AG, Neubiberg (DE)

(72) Inventors: Horst THEUSS, Wenzenbach (DE); Rainer Markus SCHALLER, Aichen (DE)

(21) Appl. No.: 19/306,285

(22) Filed: Aug. 21, 2025

(30) Foreign Application Priority Data
Sep. 13, 2024 (DE) 102024208740.8

(51) Int. Cl. G01R 15/20; G01R 19/00

(52) U.S. Cl. CPC G01R 15/202; G01R 15/205; G01R 19/0092

(57) ABSTRACT

A current sensing system includes a sensor unit arranged in a sense current path and configured to sense a current density in the sense current path, a switching unit configured to receive a control signal and in reaction to receiving the control signal, connect a bypass resistor in parallel to the sensor unit forming a controllable bypass current path.

### CROSS-REFERENCE TO RELATED APPLICATION

This application claims priority to Germany Patent Application No. 102024208740.8 filed on Sep. 13, 2024, the content of which is incorporated by reference herein in its entirety.

### TECHNICAL FIELD

The present disclosure relates to a current sensing system comprising a sensor unit arranged in a sense current path and configured to sense a current density in the sense current path. The disclosure further relates to a current sensing device.

### BACKGROUND

Common current sensors have a limited resolution and limited measurement range. This applies particularly to sensors using the Hall principle (Hall-Sensors) and tunnel magneto resistive sensors (TMR Sensors).

In many applications Hall sensors and TMR sensors are located inside molded packages. If wider measurement ranges need to be sensed, it has been proposed to use plural sensors for different sections of the measurement range.

Hence, there is a general need for packaged sensor systems having a wider measurement range. Moreover, at high currents, thermal management of sensors inside molded packages becomes necessary.

Therefore, there is an additional need for packaged sensor systems having a widened measurement range together with increased thermal capability.

### SUMMARY

According to a first aspect of the disclosure a current sensing system is provided, the system including: a sensor unit arranged in a sense current path and configured to sense a current density in the sense current path, a switching unit configured to receive a control signal and in reaction to receiving the control signal, connect a bypass resistor in parallel to the sensor unit forming a controllable bypass current path.

In a sense current path, which may also be referred to as a current measurement path, a sensor unit is arranged. The sensor unit may be any kind of current sensor but may be particularly a current sensor based on magnetic flux sensing. Any sensors have a predefined measuring range, that is, a range of current which they are configured to sense with a certain predefined resolution. However, currents in the current measurement path exceeding the current measuring range of the sensors, cannot be sensed due to saturation effects in the sensor.

Therefore, upon reaching a certain threshold current corresponding to a threshold current density in the sense current path, a control signal is provided. A switching unit, which is configured to receive the control signal, then connects a bypass resistor in parallel to the sensor unit. Thereby, a parallel connection of the bypass resistor and the resistance of the sensor unit is facilitated. Hence, a certain amount of the overall current in the sense current path will flow via the bypass resistor and a respectively lower amount will flow through the sensor unit. As the amount of current flowing through the bypass resistor is known, the overall current can be determined by calculating a value of the bypass current and adding the value of the current sensed by the sensor unit. Hence, an extended measuring range of the sensor unit is provided.

$$The amount of the overall current is Ioverall = Isensed * ( 1 + Rsenor unit / Rbypass ) .$$

Firstly, the sensor unit may be used to sense higher overall currents, since higher currents at the sensor unit are possible at higher overall currents. Typically, in a DSO 300 MIL housing a current sensing system having a measuring range up to 50 Ampere is provided. By extending the measuring range according to the disclosure, current sensing at least 70 Ampere is possible with standard sensors.

Secondly, a resolution of the sensor unit may be enhanced wherein the overall current sensing capability of the current sensing system is kept constant. That is, a standard resolution of, for example, 200 mA at a maximum current value of 50 A could be further reduced, while maintaining the maximum current value. This is particularly relevant at battery management systems, where relatively high load currents need to be monitored, but e.g., detection of very low leakage currents is also desirable at the same time.

Thirdly, at currents extending the measuring range of a magnetic current sensor, the magnetic current sensor enters in a saturated state, that is a saturation of the measured magnetic flux density. However, with decreasing currents the saturation will not completely be reversible, but the sensor may show hysteresis-effects regarding the magnetic flux density. The hysteresis-effects may influence the measuring accuracy. Hence, the extended measuring range may be advantageous for protecting magnetic current sensors from damage by over currents.

Fourthly, by splitting the current path, thermal effects caused by the ohmic resistance in the sense current path and in the bypass current path may be more evenly distributed. Hence, splitting up the sense current path may also be used for managing a distribution of thermal energy within the current sensing system.

In an implementation, the switching unit is a controllable semiconductor element, and the bypass resistor is an internal resistance of the controllable semiconductor element. The switching unit may be particularly a controllable semiconductor transistor die. The controllable semiconductor transistor die has an internal resistance which may be referred to as the drain-source-on-resistance, RDS,ON. That is, in a switched ON-state, when the bypass current path is conducting, by the switching unit, a resistance of the bypass current path is provided by the RDS,ON of the semiconductor transistor die. No extra bypass resistor is needed. If the controllable semiconductor element is a MOSFET, the drain-source-on-resistance RDS,ON can also be referred to as collector-emitter-on-resistance.

In an implementation the system includes logic configured to provide the control signal to the switching unit.

In a further implementation, the current sensing system includes a leadframe forming the sense current path, wherein the leadframe has a first and a second portion, each portion of the first and the second portion including a set of external connectors. The sense current path may be a section of a lead frame but may also be any other electrical connection. For example, the sense current path may be formed at an insulator substrate by a structured metallization layer forming different functional portions. Each portion of the first and second portions of the leadframe may have a set of connectors. The external connectors may connect the current sensing system to the outside world. The external connectors may be leads, which are integral parts of the leadframe, but may also be separate pins or wires having respective mutual connections portions at the leadframe. The first set of external connectors may be current inlet connectors and the second set of external connectors may be current outlet connectors.

In an implementation, the leadframe includes a third portion, wherein the third portion includes a bottleneck portion and wherein the third portion is arranged between the first portion and the second portion of the leadframe.

The third portion may be an interconnect portion connecting the first and second portion of the leadframe, that is forming an interconnection between the current inlet connectors and the current outlet connectors. The third portion is also part of the sense current path. The third portion may include or consist of a bottleneck portion. That is, the third portion may be shaped or otherwise configured to provide a current measurement portion in which the current in the sense current path is actually sensed. The third portion may hence be configured to match the constraints of the sensor unit for proper current sensing.

Especially, the third portion may include an apex portion, configured to foster a higher current density during operation of the current sensing system than a current density in other portions of the sense current path, and wherein the sensor unit is arranged adjacent to the apex portion.

The apex portion may be the apex of a V or U shape of the third portion. The sensor unit may be arranged adjacent to the apex portion and separated from the apex portion by a separation layer. The separation layer may be one of a mold compound, an underfill material like polyimide or a glass substrate. The separation layer may be arranged between the leadframe and the sensor unit.

In an implementation the first portion and/or the second portion is configured to carry the controllable semiconductor element. The first portion of the leadframe or the second portion of the leadframe may serve as a die carrier, or a die pad configured for attaching the controllable semiconductor element. Particularly, the controllable semiconductor element may be attached to the first or second portion of the leadframe by a connection layer which may be arranged between the die carrier and a backside first load electrode of the controllable semiconductor die. The connection layer may be built up, for example, by soft soldering, sintering or diffusion soldering.

In an implementation the controllable semiconductor element is a transistor, preferably one of a MOSFET, a JFET, an IGBT, a GaN HEMT or a bipolar transistor; and wherein the controllable semiconductor element includes the first load electrode, a second load electrode and a control electrode, wherein the control signal is received, from the logic, via the control electrode.

The controllable semiconductor element is coupled between the first and the second portion of the leadframe, forming the controllable bypass current path. For example, the controllable semiconductor element may be coupled to the first portion of the leadframe with the first load electrode.

That is, the first load electrode may be coupled to a first surface of the first portion of the leadframe and the second load electrode may be coupled to a first surface of the second portion of the leadframe by bond wires or a clip. The second portion of the leadframe may include a landing portion, to which electrical connectors from the second load electrode are electrically bonded. The landing portion may also be a diode which may be attached to the first surface of the second portion of the leadframe. Thus, the controllable bypass current path is defined between the first load electrode of the controllable semiconductor element at the first portion of the leadframe and the landing portion at the second portion of the leadframe. The control electrode may be electrically coupled to the logic.

Particularly, the logic may be a gate driver logic, configured to receive a current value from the sensor unit, and when the current value reaches a predefined threshold, generate a gate signal for the controllable semiconductor element.

If the controllable semiconductor element is a normally-off element, the element may be set into an On-state upon reception of the gate signal, thereby enabling a bypass current flow via the controllable bypass current path. If the controllable semiconductor element would be a “normally-on element”, the signal logic would be reversed. The controllable semiconductor element may be configured to remain in the ON-state as long as the control/gate signal is present, that is as long as the signal level at the control electrode is high. If the received current value from the sensor unit falls below the predefined threshold, the gate signal may be set to low, by the logic. When the gate signal is low, the controllable semiconductor element may be switched into an OFF-state, which may be a non-conductive state, thereby interrupting the current flow via the bypass current path.

Alternatively, the gate signal may be terminated if a second predefined threshold value of the sensed current is reached.

In an implementation the current sensing system includes an encapsulant, encapsulating at least part of the first portion, the second portion and the third portion of the leadframe, the switching element and the sensor unit, the encapsulant forming a molded package of the current sensing system. The encapsulant may form a mold body of a molded package.

In an implementation the current sensing system is a Dual-In-Line Package (DIP). A DIP is a rectangular molded package with two parallel rows of electrical connecting pins, also known as leads. These pins may be spaced evenly apart and are typically 0.1 inches (2.54 mm) apart, which is a standard spacing in the electronics industry. The current sensing system may be configured to be inserted into a socket or mounted directly onto a printed circuit board (PCB) using through-hole technology (THD). However, the package may also be a Surface Mount Device (SMD).

In an implementation a second surface of the first portion of the leadframe and/or a second surface of the second portion of the leadframe, which is opposite the first surface, is configured to be thermally coupled to a heatsink.

At higher currents, thermal management of the sensor system becomes more important, that is, heat removal from the molded package may be required. By thermally coupling the second surface, that is, the backside surface, of the first and second portion of the leadframe to a heatsink, heat generated by ohmic resistance in the sense current path and in the bypass current path may be led away from the sensor unit and from the controllable semiconductor die.

Therefore, the molded package may include a recess overhead the second surfaces of the first and second portion of the leadframe, the recess exposing the second surfaces and forming an outermost surface of the molded package. By the recess, the encapsulant may be completely removed from the backsides of the first and second portions of the leadframe. The backsides of the first and second portions of the leadframe may be exposed, forming exposed die pads. The backsides of the first and second portions of the leadframe may form a planar surface at the outermost surface of the molded package or may be exposed inside the recesses.

In an implementation, a Thermal Interface Material, TIM, is arranged in contact with the second surface being exposed in the recess, the TIM filling the recess to form an outermost planar surface of the molded package. By using a TIM, the exposed backsides of the first and second portions of the leadframe are covered by an electrically insulating but thermally conductive material.

In an implementation the first and the second set of external connectors protrude out of the package body at a first portion of a circumferential surface and wherein external sense connectors being connected to the sensor unit, protrude out of a second portion of the circumferential surface opposite the first portion of the circumferential surface. At a DIP the first and second set of external connectors, that is, the current connectors, protrude out of a first side of the package body, whereas the external sense connectors protrude out of a second side of the package body opposite the first side.

In an implementation the sensor unit includes the logic; or the sensor unit includes a housing and the logic is an Application Specific Integrated Circuit, ASIC, being arranged within the housing of the sensor unit; or the logic is included in a logic unit. The logic may be part of the sensor unit, or included in the sensor unit or may be spaced apart from the sensor unit in another part of the system.

In an implementation the current sensing system includes a heatsink; and/or a solid-state circuit breaker configured to interrupt a load current path upon reception of a second control signal from the logic; and/or the logic unit.

Besides the heatsink, the system may further include a solid-state circuit breaker (SSCB). Upon measuring a current value, which may exceed a third threshold, the logic may generate a second control signal for the SSC. The SSC may interrupt the sense current path upon reception of the second control signal.

In an implementation the sensor unit is configured to sense the current density by measuring a magnetic field or a magnetic flux density; particularly, the sensor unit includes one of a Hall sensor, a giant magnetoresistive (GMR) sensor GMR-Sensor, an anisotropic magnetoresistive (AMR) sensor, or a tunnel magnetoresistive (TMR) sensor.

According to a second aspect of the disclosure, a sensor device is provided, the sensor device including: a sensor unit arranged in a sense current path, logic configured to provide a control signal; a switching unit configured to receive the control signal and in reaction to receiving the control signal, connect a bypass resistor in parallel to the sensor unit forming a controllable bypass current path, an encapsulant forming a molded package of the sensor device; a leadframe including a first portion and a second portion and a third portion, the third portion forming a bottleneck portion of the sense current path; wherein the switching unit, in an ON state, has an internal resistance forming the bypass resistor and is coupled between the first and the second portion forming the controllable bypass current path, and wherein the sensor unit is arranged adjacent to the bottleneck portion.

### BRIEF DESCRIPTION OF THE DRAWINGS

Example implementations of the disclosure are described with reference to the following figures:

FIG. 1 shows a schematic view of an example implementation of the disclosure.

FIG. 2 is a circuit diagram of some aspects of the disclosure.

FIG. 3 is a schematic diagram of some aspects of the disclosure.

FIG. 4 is a cross-sectional view of some implementations of the disclosure.

FIG. 5 is a three-dimensional view of an example package of the disclosure.

FIGS. 6A-6D show further implementations of example bypass connections according to the disclosure.

### DETAILED DESCRIPTION

In the following detailed description, reference is made to the accompanying drawings. The drawings show specific examples in which the implementation may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (e.g., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connected pads and includes at least one semiconductor element with electrodes. The pads are electrically connected to the electrodes which includes that the pads are the electrodes and vice versa.

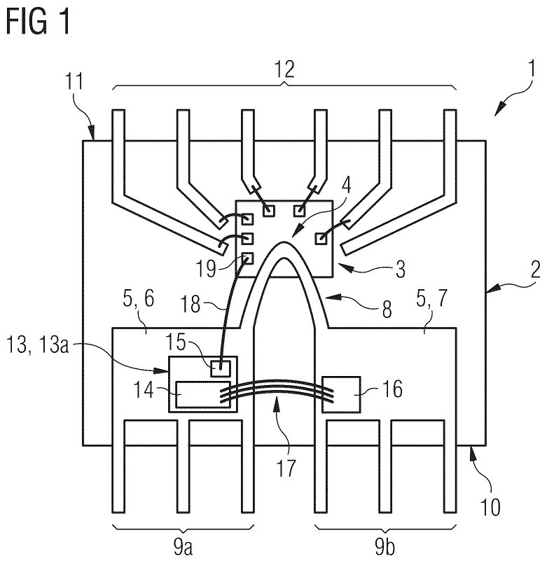

FIG. 1 shows a current sensing system 1. The current sensing system 1 comprises a package body 2. The package body 2 consists of an encapsulant, which can be a mold compound. The current sensing system 1 comprises a sensor unit 3. The sensor unit 3 is arranged overhead an apex portion 4 of a leadframe 5.

The leadframe 5 comprises a first portion 6 and a second portion 7 and a third portion 8. The third portion 8 is a bottleneck portion 8. The apex portion 4 is part of the bottleneck portion 8.

Both the first portion of the lead frame 6 and the second portion of the lead frame 7 form die pads. The leadframe 5 forms a sense current path. Particularly, both the first portion of the lead frame 6 and the second portion of the lead frame 7 comprises a set of external connectors 9.

A first set of external connectors 9a is connected to the first portion of the lead frame 6 and forms a current inlet portion, wherein a second set 9b of external connectors is connected to the second portion of the lead frame 7 and forms a current outlet portion.

A load current path is established between the first set of external connectors 9a and the second set of external connectors 9b via the third portion 8 of the leadframe.

The first and the second set of external connectors 9a,9b protrude out of the mold compound at a first circumferential surface 10 of the package body 2. At a second circumferential surface 11 of the package body 2, a set of external sense connectors 12 protrudes out of the package body 2. The sensor unit 3 is electrically connected to the external sense connectors 12, for example by wire bonds.

At the first portion of the lead frame 6, which forms a die pad, a switching element 13 is arranged. The switching element 13 is a semiconductor transistor die 13a. The semiconductor transistor die 13a comprises a first load electrode 36 (not visible) at the lowermost surface, by way of which it is attached to the first portion of the lead frame 6. Further, the semiconductor transistor die 13a comprises a second load electrode 14 and a control electrode 15. The second load electrode 14 and the control electrode 15 are arranged at an uppermost surface opposite the lowermost surface at which the first load electrode 36 is arranged. The second load electrode 14 is coupled to a landing portion 16 of the second portion of the lead frame 7 by a first electrical connector 17.

To ensure a respective safety distance, which accords to the applied voltages, the first portion 6 of the lead frame 5 is adequately spaced apart from the second portion 7 of the lead frame 5. Additionally, to enhance a creepage distance between the first and the second portion 6,7 of the leadframe 5, a recess/pocket may be arranged at the first circumferential surface 10 of the package body 2 (not visible).

The control electrode 15 of the semiconductor transistor die 13a, which is an example for the controllable semiconductor element, is electrically coupled by a second electrical connector 18 to the sensor unit 3.

The sensor unit 3 comprises a logic IC 19, to which the control electrode 15 is connected. The logic IC 19, which is configured to generate a control signal, which is a gate signal, and to provide the gate signal via the second electrical connector 18 to the control electrode 15 of the semiconductor transistor die 13a. Upon reception of the gate signal, the semiconductor transistor die 13a is set to an ON-state, that is, electrically connects the first portion of the leadframe 6 via the first electrical connector 17 to the second portion of the leadframe 7. In the ON-state, the semiconductor transistor die 13a electrically connects the first and the second portion 6,7 of the leadframe 5 forming a bypass current path parallel to the load current path. As a result, a part of the incoming current is led via the semiconductor transistor die 13 and the first electrical connectors 17 directly to the second portion 7 of the lead frame 5. This part of the current hence bypasses the third portion 8 of the leadframe 5 and hence bypasses the sensor unit 3. As a result, a diminished part of the current is led via the third portion 8 and thus passes the sensor unit 3.

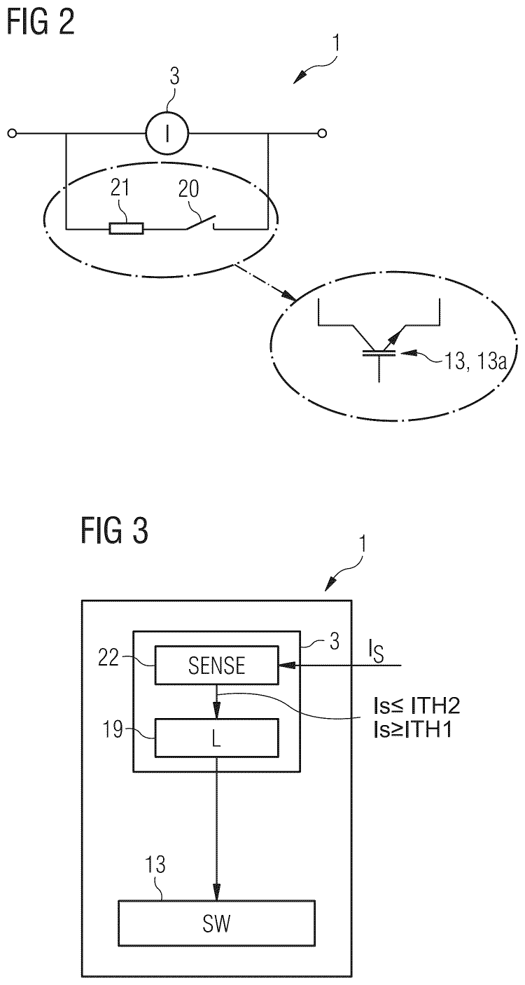

FIG. 2 shows a schematic view of the current sensing system 1. The sensor unit 3 is a current measurement unit. A switch 20 and a bypass resistor 21 are arranged in parallel to a sense current path passing the sensor unit 3. By closing the switch 20, a bypass current path is established via the bypass resistor 21 and the switch 20, parallel to the sensor unit 3.

According to the present disclosure the switch 20 and the bypass resistor 21 are both comprised in the semiconductor transistor die 13a. Thereby the resistance of the bypass resistor 21 equals the transistor die's drain-source on resistance RDS,ON, that is the transistor die's resistance if set in the ON-state by a gate signal.

FIG. 3 shows a schematic diagram of the present disclosure. The current sensing system 1 comprises the sensor unit 3 and the switching element 13.

The sensor unit 3 comprises the logic IC 19 and a magnetic current sensor 22. The logic is a gate driver logic.

The magnetic current sensor 22 is configured to measure a magnetic field, preferably at a portion of the load current path having a high current density, that is, for example the apex portion 8.

An input value Is of the sensed current is provided to the logic IC 19. The logic IC 19 is configured to receive the sensed current value Is and to compare the sensed current value Is with a predefined first threshold value ITH,1. If the sensed current value Is equals or exceeds the predefined threshold value ITH,1, the logic IC 19 is configured to generate the control signal, and to provide the control signal to the switching element 13. The switching element is set into the ON-state, by the control signal, and remains in the ON-state as long as the control signal is present.

Upon reception of the control signal, the switching element 13 opens the bypass current path.

If the sensed current IS value falls below a predefined second threshold value ITH,2 the logic IC 19 is configured to terminate the control signal. ITH,1 may equal ITH,2. Upon termination of the control signal, which is a gate signal, the switching element 13 is set from the ON-state into a non-conductive OFF-state thereby interrupting the bypass current path.

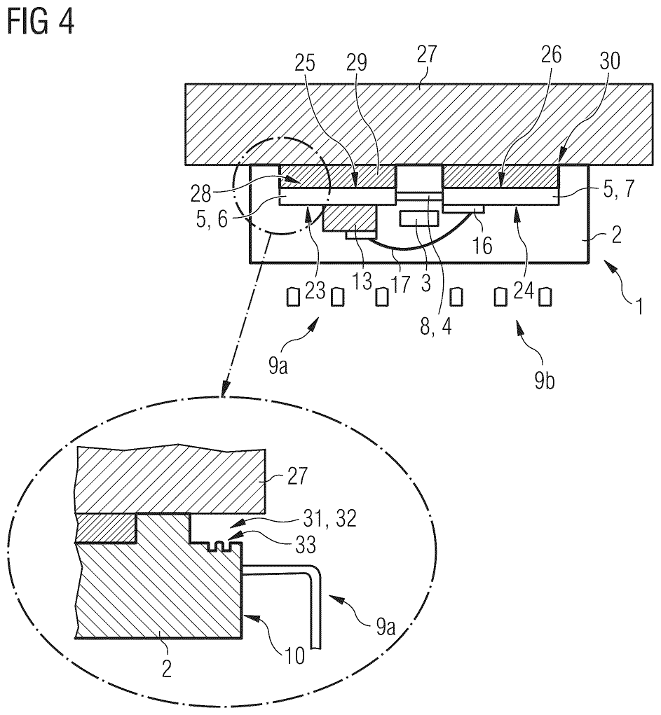

FIG. 4 shows a further implementation of the current sensing system according to the disclosure.

The switching unit 13 is attached to a first surface 23 of the first portion 6 of the leadframe 5 and electrically coupled, by the first electrical connector 17, to a first surface 24 of the second portion 7 of the leadframe 5. A second surface 25 of the first portion 6 of the leadframe 5 and a second surface 26 of the second portion 7 of the leadframe 5 are thermally coupled to a heatsink 27.

The mold compound 2 comprises a recess 28, the recess 28 exposing both the second surface 25, 26 of the first portion 6 of the leadframe 5 and the second portion 7 of the leadframe 5. The recess 28 is filled with a Thermal Interface Material (TIM) 29. Together with the mold compound, the TIM 29 forms a planar uppermost surface 30 of the package body 2 of the current sensing system 1.

In the extended view of FIG. 4, an edge portion 31 of the molded package 2 is shown. The edge portion 31 comprises a step 32 and a groove structure 33 to increase a creepage distance from the external connectors 9a to the heatsink 27.

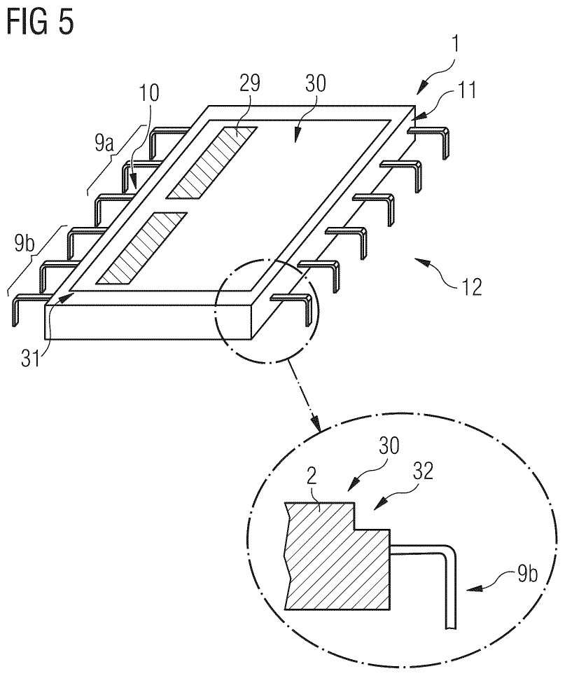

FIG. 5 shows a further implementation of the current sensing system according to the disclosure. The current sensing system is a Dual-In-Line Package (DIP). The first and the second set 9a,9b of external connectors protrude out of a circumferential surface of the package body 2 at opposite sides. The first set of external connectors 9a protrudes out of the first circumferential surface 10 wherein the second set of external connectors 9b protrudes out of the second circumferential surface 11, opposite the first circumferential surface 10. The planar uppermost surface 30 is formed by the mold compound 2 and the TIM 29 with which the recesses 28 in the mold compound are filled. The planar uppermost surface 30 comprises two TIM 29 portions to couple the first and second portions 6,7 of the leadframe 5 to a heatsink 27 (not shown).

Step 32 is again shown in the extended view of FIG. 5. By step 32, which forms a wraparound edge of the uppermost surface of the package body 2, the planar uppermost surface 30 forms a hump.

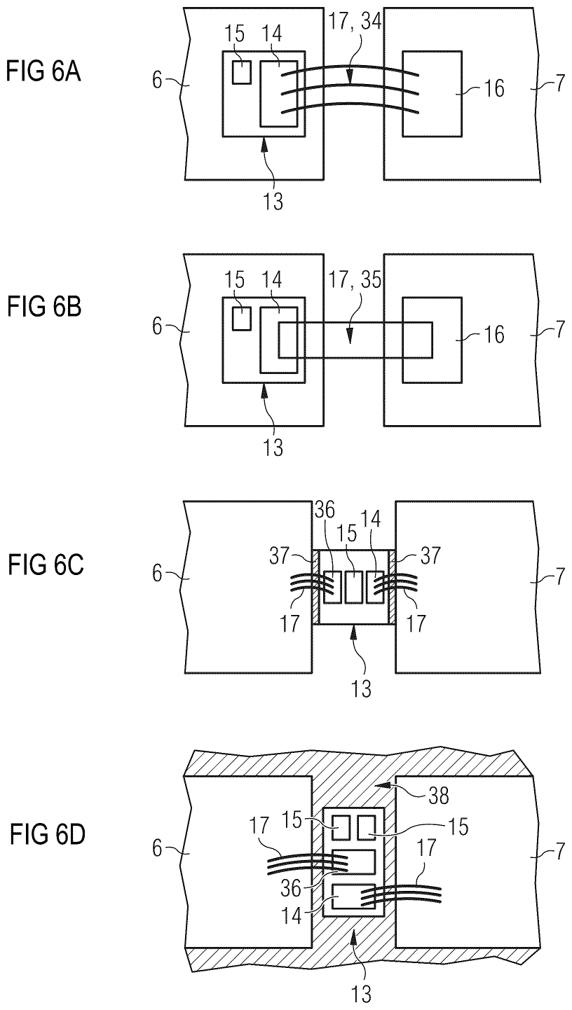

FIGS. 6A-6D show several implementations of the switching element 13 connecting the first portion 6 of the leadframe 5 with the second portion 7 of the leadframe 5.

In FIG. 6A the switching element 13 is a vertical transistor die 13a being connected to the landing portion 16 by the first electrical connector 17. The first electrical connector 17 comprises bond wires 34.

In FIG. 6B the first electrical connector 17 is a clip 35, enabling higher ampacity.

In FIG. 6C the switching element 13 is a lateral semiconductor transistor die 13, for example a GaN HEMT or a lateral SiC MOSFET. The transistor die 13 is arranged between the first portion 6 of the leadframe 5 and the second portion 7 of the leadframe 5. A first load electrode 36 is coupled to the first portion 6 of the leadframe 5. The second load electrode 14 is coupled to the second portion of the leadframe 7. Isolating portion 37 is of an electrically isolation material and electrically isolates lateral faces of the transistor die 13 towards the respective portions of the leadframe 6,7.

In FIG. 6D the switching element 13 is a lateral device and arranged at an isolated portion of a substrate or in the mold compound. In this implementation, the leadframe 5 may be a first section of a metallization layer, wherein the metallization layer is disposed on an insulator substrate 38. The switching element 13 may be disposed on an island portion of the insulator substrate 38 between the first and the second portion 6,7 of the leadframe 5. The first load electrode 36 is coupled to the first portion 6 of the leadframe 5 and the second load electrode 14 is coupled to the second portion 7 of the leadframe 5.

The switching element 13 comprises two gate electrodes 15, wherein one gate electrode may be configured to receive an ON signal and the respective other gate electrode may be configured to receive an OFF signal.

### LIST OF REFERENCE SIGNS

1 current sensing system
2 package body/mold compound
3 sensor unit
4 apex portion
5 leadframe
6 first portion of the leadframe
7 second portion of the leadframe
8 third portion of the leadframe/bottleneck portion
9 external connectors
9a first set of external connectors
9b second set of external connectors
10 first circumferential surface
11 second circumferential surface
12 external sense connectors
13 switching element
13a semiconductor transistor die
14 second load electrode
15 control electrode
16 landing portion
17 first electrical connector
18 second electrical connector
19 logic IC
20 switch
21 bypass resistor
22 magnetic current sensor
23 first surface of first portion of leadframe
24 first surface of second portion of leadframe
25 second surface of first portion of leadframe
26 second surface of second portion of leadframe
27 heatsink
28 recess
29 TIM
30 planar uppermost surface
31 edge portion
32 step
33 groove structure
34 bond wires
35 clip
36 first load electrode
37 isolating portion
38 insulator substrate

1. A current sensing system, comprising:
a sensor unit arranged in a sense current path and configured to sense a current density in the sense current path; and
a switching unit configured to receive a control signal and in reaction to receiving the control signal, connect a bypass resistor in parallel to the sensor unit forming a controllable bypass current path.

2. The current sensing system of claim 1, wherein the switching unit is a controllable semiconductor element, and
wherein the bypass resistor is an internal resistance of the controllable semiconductor element.

3. The current sensing system of claim 2, further comprising:
logic configured to provide the control signal to the switching unit.

4. The current sensing system of claim 3, further comprising:
a leadframe forming the sense current path, wherein the leadframe has a first portion and a second portion, each portion of the first portion and the second portion comprising a set of external connectors.

5. The current sensing system of claim 4, wherein the leadframe comprises a third portion,
wherein the third portion comprises a bottleneck portion, and
wherein the third portion is arranged between the first portion and the second portion of the leadframe.

6. The current sensing system of claim 5, wherein the third portion comprises an apex portion, configured to foster a higher current density during operation of the current sensing system than a current density in other portions of the sense current path, and
wherein the sensor unit is arranged adjacent to the apex portion.

7. The current sensing system of any of claim 4, wherein the first portion and/or the second portion is configured to carry the controllable semiconductor element.

8. The current sensing system of any of claim 4, wherein the controllable semiconductor element is coupled between the first and the second portion of the leadframe, forming the controllable bypass current path.

9. The current sensing system of any of claim 4, wherein the controllable semiconductor element is a transistor,
wherein the controllable semiconductor element comprises a first load electrode, a second load electrode, and a control electrode, and
wherein the control signal is received, from the logic, via the control electrode.

10. The current sensing system of claim 9, wherein the first load electrode is coupled to a first surface of the first portion of the leadframe,
wherein the second load electrode is coupled to a first surface of the second portion of the leadframe by bond wires or a clip, and
wherein the control electrode is coupled to the logic.

11. The current sensing system of any of claim 3, wherein the logic is a gate driver logic, configured to:
receive a current value from the sensor unit, and
upon reaching a predefined threshold of the current value, generate a gate signal for the controllable semiconductor element.

12. The current sensing system of claim 11, wherein the controllable semiconductor element is set into an on-state upon reception of the gate signal, thereby enabling a bypass current flow via the controllable bypass current path.

13. The current sensing system of claim 5, further comprising:
an encapsulant, encapsulating at least part of the first portion, the second portion, and the third portion of the leadframe, the switching unit, and the sensor unit,
the encapsulant forming a molded package of the current sensing system.

14. The current sensing system of claim 13, wherein the current sensing system is a Dual-In-Line Package (DIP).

15. The current sensing system of any of claim 10, wherein a second surface of the first portion of the leadframe and/or a second surface of the second portion of the leadframe, which is opposite the first surface, is configured to be thermally coupled to a heatsink.

16. The current sensing system of any of claim 13, wherein the molded package comprises a recess overhead the second surfaces of the first and second portion of the leadframe, the recess exposing the second surfaces and forming an outermost surface of the molded package.

17. The current sensing system of claim 16, wherein a thermal interface material (TIM) is arranged in contact with the second surface being exposed in the recess, the TIM filling the recess to form an outermost planar surface of the molded package.

18. The current sensing system of any of claim 13, wherein a first set of external connectors and a second set of external connectors protrude out of a package body at a first portion of a circumferential surface of the package body, and
wherein external sense connectors, being connected to the sensor unit, protrude out of a second portion of the circumferential surface opposite the first portion of the circumferential surface.

19. The current sensing system of any of claim 3, wherein the sensor unit comprises the logic, or
wherein the sensor unit comprises a housing and wherein the logic is an application specific integrated circuit (ASIC) being arranged within the housing of the sensor unit, or
wherein the logic is comprised in a logic unit.

20. The current sensing system of claim 19, further comprising:
a heatsink; and/or
a solid-state circuit breaker configured to interrupt a load current path upon reception of a second control signal from the logic; and/or
the logic unit.

21. The current sensing system of claim 1, wherein the sensor unit is configured to sense the current density by measuring a magnetic field,
wherein the sensor unit comprises one of a Hall sensor, a giant magnetoresistive (GMR) sensor, an anisotropic magnetoresistive (AMR) sensor, or a tunnel magnetoresistive (TMR) sensor.

22. A sensor device, comprising:
a sensor unit arranged in a sense current path;
logic configured to provide a control signal;
a switching unit configured to receive the control signal and in reaction to receiving the control signal, connect a bypass resistor in parallel to the sensor unit forming a controllable bypass current path;
an encapsulant forming a molded package of the sensor device; and
a leadframe comprising a first portion and a second portion and a third portion, the third portion forming a bottleneck portion of the sense current path,
wherein the switching unit, in an ON state, has an internal resistance forming the bypass resistor and is coupled between the first and the second portion forming the controllable bypass current path, and wherein the sensor unit is arranged adjacent to the bottleneck portion.
